(19) United States
(12) Patent Application Publication
(10) Pub. No.: US 2026/0226645 A1
(43) Pub. Date: Aug. 6, 2026

(54) Electrodeposition of Thin Copper Films on Conductive Substrates

(71) Applicant: MacDermid Enthone Inc., Waterbury, CT (US)

(72) Inventors: Lian Guo, Slingerlands, NY (US); Jianwen Han, Southbury, CT (US); Eric Yakobson, East Haven, CT (US); Wenbo Shao, New Canaan, CT (US); Kyle M. Whitten, Cheshire, CT (US); Elie H. Najjar, Norwood, MA (US)

(21) Appl. No.: 19/145,142

(22) PCT Filed: Jan. 16, 2024
(86) PCT No.: PCT/US24/11616

§ 371 Date: Jul. 1, 2025

Related U.S. Application Data
(60) Provisional application No. 63/439,657, filed on Jan. 18, 2023.

(51) Int. Cl. C25D 3/38; C25D 5/38

(52) U.S. Cl. CPC C25D 3/38; C25D 5/38

(57) ABSTRACT

A copper electrolyte comprising (a) a water soluble copper salt; (b) a complexant; (c) a leveler; (d) optionally a polar solvent; (e) optionally, a pH adjuster; and (f) balance water. The copper electrolyte has a pH in the range of about 8 to about 11, preferably about 8.2 to about 9.5. The copper electrolyte can be used to deposit an ultrathin copper layer on a conductive substrate that is free of pinholes and other defects and that suppresses metal dissolution.

### FIELD OF THE INVENTION

The present invention relates generally to a copper electrolyte and a method of electrodepositing copper film on a conductive substrate.

### BACKGROUND OF THE INVENTION

One sequence commonly used for fabricating copper interconnects is called the “dual-damascene” process. To form electrical interconnects, dielectric layers are patterned to create features within which metal interconnects will be formed. In general, a feature used to form a metal interconnect is a depression having any shape formed in a substrate or layer deposited on the substrate.

Since copper is difficult to etch and has a high diffusivity in many materials, the interconnects are generally produced by a sequence of steps comprising:
a. deposition of an insulating dielectric layer;
b, etching of the interconnect features in the said dielectric layer;
c. deposition of a barrier layer (generally made of tantalum, titanium nitride, tantalum nitride, tungsten nitride or tungsten carbide, for example) used to prevent copper migration;
d. filling of the lines and interconnection holes with copper; and
e. removal of the excess copper by chemical mechanical polishing.

This sequence of steps is known by the name “Damascene process”, which has been described for example by C. Y. Chang and S. M. Sze “ULSI Technology”, McGraw-Hill, New York, (1996), pages 444-445.

Electronic connections between electronic devices in an integrated circuit (IC) chip are currently typically created using copper metal or alloys of copper metal. Devices in an IC chip can be placed not only across the surface of the IC chip but devices can also be stacked in a plurality of layers on the IC chip. Electrical interconnections between electronic devices are built using features, which may include one or more vias and/or trenches, that are filled with conducting material. Layer(s) of insulating materials, frequently, low-k dielectric materials, separate the various components and devices in the IC chip. The substrate on which the devices of the IC circuit chip are built is, for example, a silicon wafer or a silicon-on-insulator substrate. Other substrates include, but are not limited to germanium, indium antimonide, lead telluride, indium arsenide, indium phosphide, gallium arsenide, gallium antimonide, and or other Group III-V materials either alone or in combination with silicon or silicon dioxide or other insulating materials.

Nanoscale features are etched in a dielectric layer (typically SiO₂) followed by deposition of diffusion barrier layer(s). A thin copper seed layer is applied, such as by sputtering, followed by copper electroplating to form complex nanopatterns. The multilayered interconnect network may contain a number of levels (e.g., 7-10 interconnect levels). Interconnects in chips' back-end-of-line (BEOL) typically distribute clock and other signals, provide power and ground for various electronic system components, and interconnect transistors within the chips' front-end-of-line (FEOL).

Barrier liner layers are used between the metal interconnects and the dielectric materials to prevent metal (i.e., copper) diffusion and electromigration into the surrounding materials. Device failure can occur, for example, in situations in which copper metal is in contact with dielectric materials because the copper metal can ionize and penetrate into the dielectric material. Barrier layers placed between a dielectric material, silicon, and or other materials and the copper interconnect can also serve to promote adhesion of the copper to the other material(s).

As the miniaturization trend in integrated circuits fabrication continues, alternative liner materials for use in connection with copper interconnects have been explored, which typically comprise conductive materials such as cobalt, tungsten, ruthenium, molybdenum, combinations of the foregoing and alloys of the foregoing. Cobalt has been widely investigated and employed due to its low resistance at nanoscales and integration compatibility, as well as the benefits of improving copper electromigration resistance. However, direct electrodeposition of copper on cobalt is problematic due in part to the stability issues of cobalt in acidic copper damascene processes. Subsequent processes of copper seeding and copper electroplating face increasing technical difficulties when widths and aspect ratios of electro-filled features become more challenging.

In BEOL copper damascene, cobalt has been used as the liner material to provide good copper seed coverage on sidewalls and longer electromigration lifetime of copper interconnects. While direct copper fill on cobalt liners without a copper seed layer has been attempted, this approach can result in high defectivity in copper fill at advanced nodes.

U.S. Pat. Nos. 10,648,097 and 11,168,407, both to Velmurugan et al, the subject matter of each of which is herein incorporated by reference in its entirety, describe electroplating systems for depositing copper on a cobalt layer.

WO2021/207254 to LAM Research Corporation describes a combination of a suppressor and an accelerator selected from the group consisting of (i) a polyallylamine (suppressor) and thiourea (accelerator); (ii) polyallylamine (suppressor) and ammonium thiocyanate (accelerator); and (iii) saccharin (suppressor) and thiourea (accelerator). These combinations are directed to the superconformal fill (i.e., via filling or gap filling) of vias and trenches.

U.S. Pat. No. 10,883,185 to Religieux et al., the subject matter of which is herein incorporated by reference in its entirety, describes an electrolyte composition for depositing copper on a metal seed layer that may include at least two materials selected from the group consisting of copper, cobalt or ruthenium, by combining two separate copper complexed electrolytes. The invention also describes a process for filling cavities with copper and a semiconductor device obtained by the process.

U.S. Pat. No. 10,472,726 to Mevellec et al., the subject matter of which is herein incorporated by reference in its entirety, describes the alkaline electroplating of copper in vias and trenches where the substrates are first lined with ruthenium or sputtered copper on TiN/Ti.

### SUMMARY OF THE INVENTION

It is an object of the present invention to provide a copper electrolyte for use in copper damascene processes.

It is another object of the present invention to provide a copper electrolyte for producing thin copper films.

It is still another object of the present invention to provide a copper electrolyte for producing an ultrathin copper film.

It is still another object of the present invention to provide a copper electrolyte for producing an ultrathin copper film on conductive substrates.

It is still another object of the present invention to provide a copper electrolyte configured to produce an ultrathin copper film on conductive substrates such as cobalt, tungsten, ruthenium, molybdenum, combinations thereof, and alloys thereof by electrodeposition.

It is still another object of the present invention to provide a method of electrochemically depositing a continuous and pin-hole free ultrathin copper, preferably a film thinner than about 2 nm on a conductive liner.

It is still another object of the present invention to provide an improved liner material for use in copper damascene processes including BEOL copper damascene processes.

To that end, in one embodiment, the present invention relates generally to a copper electrolyte comprising:
a. a water soluble copper salt:
b. a complexant;
c. a leveler;
d. optionally a polar solvent;
e. optionally, a pH adjuster; and
f. balance water,
   wherein the copper electrolyte has a pH in the range of about & to about 11, preferably about 8.2 to about 9.5.

In another embodiment, the present invention relates generally to a method of depositing a copper film on a conductive substrate, the method comprising the steps of:
a) optionally, pretreating the conductive substrate, wherein the pretreatment step removes surface oxides; and
b) immersing the conductive substrate into a copper electrolyte, wherein the copper electrolyte comprises:
   a. a water soluble copper salt;
   b. a complexant;
   c. a leveler;
   d. optionally a polar solvent;
   e. optionally, a pH adjuster; and
   f. balance water,
      wherein the copper electrolyte has a pH in the range of about 8 to about 11, preferably about 8.2 to about 9.5, and
c) electrodepositing the copper film on the conductive substrate using the copper electrolyte described herein, wherein the copper film is an ultrathin copper film having a thickness of less than about 5 nm, wherein the ultrathin copper film is a continuous copper film that is free of any pinholes or other defects.

### BRIEF DESCRIPTION OF THE FIGURES

Features and aspects of embodiments are described below with reference to the accompanying drawings, in which elements are not necessarily depicted to scale, and in certain views, parts may have been exaggerated or removed for purposes of clarity.

Exemplary embodiments of the present disclosure are further described with reference to the appended figures. It is to be noted that the various features, steps and combinations of features/steps described below and illustrated in the figures can be arranged and organized differently to result in embodiments which are still within the scope of the present disclosure.

The present invention will now be described with reference to the following figures, in which:

FIGS. 1(a) to 1(c) depict surface morphologies of different copper amounts deposited on cobalt substrates.

FIG. 2 depicts the dependence of substrate sheet resistance on the nominal thickness of copper films.

FIGS. 3(a) to 3(e) depict the Auger surface mapping of a thin copper film of 1.4 nm thickness on a cobalt substrate.

FIGS. 4(a) to 4(c) depicts surface morphologies of copper electrodeposition on tungsten substrate at different process stages or conditions.

### DETAILED DESCRIPTION OF THE PREFERRED EMBODIMENTS

It should be understood that the disclosed embodiments are merely illustrative of the present disclosure, which may be embodied in various forms. Therefore, details disclosed herein with reference to exemplary assemblies/fabrication methods and associated processes/techniques of assembly and use are not to be interpreted as limiting, but merely as the basis for teaching one skilled in the art how to make and use the advantageous assemblies/systems described herein.

As used herein, “a.” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath”, “below”, “lower”, “above” “upper”, “front”, “back”, and the like, are used for ease of description to describe one element or feature's relationship to another element(s) or feature(s). It is further understood that the terms “front” and “back” are not intended to be limiting and are intended to be interchangeable where appropriate.

As used herein, the terms “comprise(s)” and/or “comprising,” specify the presence of stated features, integers, steps, operations, elements, and/or components, but do not preclude the presence or addition of one or more other features, integers, steps, operations, elements, components, and/or groups thereof.

As used herein the term “substantially-free” or “essentially-free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically methods.

As used herein, the term “sheet resistance” refers to a quantity used for measuring electrical resistance of thin films or layers. It is expressed in ohms/square and is equivalent to the resistivity for a two-dimensional system, that is to say one in which the current flows in the plane of the layer and not in a plane perpendicular to this layer. Mathematically, the value of the sheet resistance is obtained by dividing the resistivity (expressed in ohms·m or microohms·cm) of the constituent material of the layer by the thickness (expressed in m or nm) of this layer.

In one embodiment, the present invention relates generally to a copper electrolyte comprising:
(2) a water soluble copper salt;
(3) a complexant;
(4) a leveler;
(5) optionally a polar solvent;
(6) optionally, a pH adjuster; and
(7) balance water,
   wherein the copper electrolyte has a pH in the range of about 8 to about 11, preferably about 8.2 to about 9.5.

In another embodiment, the present invention relates generally to a copper electrolyte consisting essentially of:
(1) a water soluble copper salt;
(2) a complexant;
(3) a leveler;
(4) 0 to 300 g/L of a polar solvent;
(5) optionally, a pH adjuster; and
(6) balance water,
   wherein the copper electrolyte has a pH in the range of about 8 to about 11, preferably about 8.2 to about 9.5.

By “consisting essentially of” what is meant is that the composition is free of any component that would render the composition incapable of forming an ultrathin copper layer on a cobalt substrate that is free of pinholes and other defects. That is, the composition is preferably at least substantially free or is free of oxidizers (i.e., nitrates, including cupric nitrate), and catalytic poisons (i.e., Hg, Pb, As, Bi, Cr, Se, and Sb).

In one embodiment, the water soluble copper salt is a water soluble copper (II) salt selected from the group consisting of copper (II) sulfate, copper (II) chloride, and copper (II) acetate. In one embodiment, the copper salt comprises copper (II) sulfate. The copper (II) salt is preferably contained in the electrolyte at a concentration within the range of about 2 to about 100 g/L. The inventors of the present invention have found that in compositions that do not contain a polar solvent, a higher concentration may be needed to provide a good result. That is, in compositions that do not include a polar solvent, the concentration of the copper (II) salt may be in the range of about 40 to about 80 g/L, more preferably about 45 to about 65 g/L, more preferably about 50 to about 60 g/L. On the other hand, in compositions that contain a polar solvent such as glycerol, the concentration of the copper (II) salt may be much lower such as in the range of about 0.1 to about 25 g/L, more preferably about 0.1 to about 10 g/L, more preferably about 0.1 to about 1 g/L. This is believed to be in part to achieve better uniformity of plated copper thin films.

In one embodiment, the complexant is selected from the group consisting of citric acid, tartaric acid, ethylenediaminetetraacetic acid (EDTA), N-(hydroxyethyl)-ethylenediaminetriacetic acid (HEDTA), ethylenediamine, 1,6 diamino-cyclohexane, diethylene-triamine, triethylene-tetramine, N,N,N,N-tetramethyl-ethylene-diamine, N,N-Bis(2-hydroxyethyl)ethylenediamine, N,N,N,N-tetrakis(2-hydroxyethyl)ethylenediamine, glycine. 2-amino-ethyl-phosphonic acid, salicylic acid, salicylbydroxamic acid, catechol, 1,2-dihydroxybenzene-4-sulfonic acid, acetylacetone, acetylacetonate, dimethylglyoxime and 1,3-diamino-propane. In one embodiment, the complexant comprises diethylenetriamine. In another embodiment, the complexant comprises one or more of N,N,N′,N′-Tetrakis(2-hydroxypropyl)ethylenediamine and ethylenediaminetetraacetic acid. In one embodiment, the complexant has a concentration within the range of about 0.1 to about 20 g/L. As with the copper (II) salt, the concentration of the complexant in the composition depends in part on whether or not the composition contains a polar solvent. That is, in compositions that do not contain a polar solvent, the concentration of the complexant may be in the range of about 4.0 to about 20 g/L, more preferably about 5.0 to about 9.0 g/L, more preferably about 4.5 to about 7.5 g/L. In contrast, in compositions that contain the polar solvent, the concentration of the complexant may be in the range of about 0.1 to about 2.0 g/L, more preferably about 0.2 to about 1.2 g/L, more preferably about 0.4 to about 0.8 g/L.

In one embodiment, the present invention also include a leveler. Suitable levelers include, but are not limited to, one or more of polyethylene imine and derivatives thereof, quaternized polyethylene imine, polyglycine, poly(allylamine), polyaniline, polyurea, polyacrylamide, poly(melamine-co-formaldehyde), reaction products of amines with epichlorohydrin, reaction products of an amine, epichlorohydrin, and polyalkylene oxide, reaction products of an amine with a polyepoxide, polyvinylpyridine, and polyvinylimidazole, by way of example and not limitation. One example of a suitable leveler is a polyethyleneimine such as a hydroxyethylated, (ethoxylated) water soluble polyethylenimine formed by reaction of a relatively high molecular weight polyethylenimine with ethylene oxide, a commercial product of which is available from BASF under the tradename Lupasol® SC-61B. In one embodiment, the concentration of the leveler is in the range of about 2 to about 25 g/L. As with the other ingredients in the composition, the concentration of the leveling agent in the composition depends in part on whether or not the composition contains a polar solvent. That is, in compositions that do not contain a polar solvent, the concentration of the leveling agent may be in the range of about 15 to about 25 g/L, more preferably about 18 to about 20 g/L. In contrast, in compositions that contain the polar solvent, the concentration of the leveling agent may be in the range of about 2 to about 8 g/L, more preferably about 3 to about 6 g/L.

In one embodiment, the electrolyte comprises a polar solvent. Examples of suitable polar solvents include, but are not limited to ethylene glycol, propylene glycol, glycerol, ethylene glycol monomethyl either, ethylene glycol monoethyl ether, ethylene glycol monopropyl ether, dipropylene glycol monomethyl ether and combinations of the foregoing. In one embodiment, the polar solvent comprises glycerol. If used, the concentration of the polar solvent is generally in the range of 150 about 250 g/L, more preferably about 175 to about 225 g/L, more preferably about 190 to about 210 g/L.

In one embodiment, the electrolyte of the present invention is at least substantially free of halide atoms. What is meant by “substantially free” is that the composition contains less than 50 ppm or less than 25 ppm or less than 10 ppm of halide atoms.

The pH of the electrolyte may optionally be adjusted with a suitable pH adjuster so as to maintain the pH at the desired level and so that the copper ions form a complex with the complexing agent. In one embodiment, the pH adjuster comprises tetraethylammonium hydroxide or tetrabutylammonium hydroxide or buffers such as borates, glycine and/or phosphates. As discussed above, pH is preferably within a range of about 7 to about 11, more preferably and about 8 to about 11, more preferably about 8.2 to about 9.5.

The electrolyte described herein can be used to provide an ultrathin copper film on a conductive substrate, which conductive substrate may include, for example, cobalt, tungsten, ruthenium, molybdenum, combinations thereof, and alloys thereof. In one embodiment, the conductive substrates comprise a cobalt or cobalt alloy substrate, such as a cobalt liner that bas been deposited on a barrier layer of an insulating dielectric layer. By “altrathin” what is meant is that the thickness of the electroplated copper layer is less than 10 nm, or less than 5 nm or less than 2 nm or less than 1 nm. At the same time, the ultrathin copper layer is continuous and pin-hole free. In one embodiment, the conductive substrate is formed by CVD deposition.

In one embodiment, the present invention is directed to a method of depositing a copper film, preferably an ultrathin copper film, on a substrate, preferably a conductive substrate, the method comprising the steps of:
a) optionally, pretreating the substrate, wherein the pretreatment step removes surface oxides; and
b) electrodepositing the copper film on the conductive substrate using the copper electrolyte described herein.

In one embodiment, the present invention comprises a method of depositing an ultrathin copper film on a conductive substrate, the method comprising the steps of:
A) optionally, pretreating the conductive substrate to removes surface oxides; and
B) immersing the conductive substrate into a copper electrolyte, wherein the copper electrolyte comprises:
   (1) a water soluble copper salt;
   (2) a complexant;
   (3) a leveler;
   (4) optionally a polar solvent;
   (5) optionally, a pH adjuster; and
   (6) balance water,
   wherein the copper electrolyte has a pH in the range of about 8 to about 11, preferably about 8.2 to about 9.5; and
C) electrodepositing the copper film on the conductive substrate using the copper electrolyte described herein, wherein the copper film is an ultrathin copper film having a thickness of less than about 5 nm or less than about 4 nm or less than about 3 nm or less than about 2 nm, wherein the ultrathin copper film is a continuous copper film that is free of any pinholes or other defects.

In the case of a fresh conductive substrate, such as a fresh cobalt substrate, the pretreatment step may be omitted. Prior to deposition, the conductive substrate may be immersed in a pretreatment solution to remove surface oxides. The pretreatment solution may contain a diluted weak acid such as a solution of about 0.1 to about 8 g/L, more preferably about 5 to about 6 g/L of citric acid or ligands which complex with cobalt cations and are capable of native cobalt oxide removal, such as tartaric acid, ethylenediamine or diethylenetriamine. The pretreatment step preferably lasts about 0 to 30 seconds, followed by a deionized water rinse. The pretreatment step can be skipped in the case of fresh cobalt substrates. What is meant by a “fresh” cobalt substrate is within a few hours after vacuum break without exposure to air. The pretreatment step can also be replaced by immersion at open-circuit condition in copper plating solutions. The immersion time varies from 0 to 60 sec.

In one embodiment, the conductive substrate is a conductive liner, which may be, for example, a cobalt liner that has been deposited on a barrier layer, such as a diffusion barrier layer made of one or more of tantalum, titanium, titanium nitride, tantalum nitride, tungsten, tungsten nitride, tungsten carbide, or manganese. The thickness of the diffusion barrier layer is generally between about 0.5 and about 20 nm and can be deposited using various techniques such as chemical vapor deposition, physical vapor deposition, or atomic layer deposition (ALD). The barrier layer is formed on a dielectric substrate and covers surfaces of the substrate, including side walls and bottoms of the feature formed therein. The aspect ratio of the features may vary from 2:1 to 20:1, for example from 3:1 to 10:1.

In one embodiment, the features have an opening dimension being from 5 to 45 nm and an aspect ratio of between about 3:1 to about 10:1.

In one embodiment, the cobalt layer has a thickness of between about 0.1 and about 3 nm, more preferably about 0.1 to about 2 nm. The cobalt liner may be formed in various ways such as chemical vapor deposition (CVD), physical vapor deposition (PVD), atomic layer deposition (ALD), electroless deposition. In one embodiment, the cobalt liner is formed by CVD. The cobalt liner layer preferably has a thickness in the range of about 0.5 and 20 nm, preferably between 1 to 10 nm, for example between 2 and 5 nm.

In one embodiment, the electrodeposition process described herein is carried out at a temperature within a range of about 20 to about 35° C., more preferably at about room temperature.

The alkaline copper electrolyte described herein can be used to deposit an ultrathin copper layer on a conductive substrate, which conductive substrate may include, cobalt, tungsten, ruthenium, molybdenum, combinations thereof, or alloys thereof, which may be a liner layer such as a cobalt liner, in a copper damascene process, including BEOL copper damascene. The ultrathin copper film may have a thickness of less than 5 nm, preferably less than 4 nm, more preferably less than 2 nm. The electrodeposited ultrathin copper layer prevents metal dissolution. That is, the ultrathin copper layer prevents dissolution caused by one or more of hydrogen evolution, copper displacement, and oxygen oxidation. Because the solution is alkaline, corrosion is not an issue. Thereafter, the thin copper film can used as a seed layer for acidic copper. That is the substrate, including the features, may be electroplated with copper using a suitable electrolyte, including an acidic copper electrolyte.

As described herein, the process of the instant invention can be used to plate an ultrathin copper layer on a conductive substrate to produce a well-adherent, nearly-pinhole free, copper electrodeposit. In one embodiment, the electrolyte described herein can be used to plate an ultrathin coper layer on a conductive substrate using an electroplating method. The electrolyte is contained in an electrolytic cell containing an anode, more preferably an inert anode, more preferably an anode selected from the group consisting of titanium coated with mixed iridium, ruthenium, platinum, rhodium, and tantalum metal oxides or platinized titanium and the conductive substrate as the cathode.

In one embodiment, the electroplating method comprises the steps of:
A) a “cold entry” step during which the said surface to be coated is brought into contact with the electrolyte described herein while the conductive substrate is maintained at an open-circuit potential condition for about 0 to about 30 seconds, more preferably greater than 0 to about 20 seconds, more preferably about 0.5 to about 10 seconds, more preferably about 1.0 to about 2.0 seconds:
B) a step of forming the coating during which time the cathode is polarized in a constant current mode to form the ultrathin copper coating on the conductive substrate; and
C) a “hot exit” step during which the substrate is removed from the electroplating bath.

The invention will now be described with respect to the following non-limiting examples.

### EXAMPLES

The electrolytic cell comprised an anode, made either of an inert metal (for example platinum-coated titanium) or of a metal identical to that constituting the seed layer, in this case copper, the silicon wafer coated with TaN or barrier layer and the conductive substrate constituting the cathode of this cell.

The electrolytic cell also included a device for supporting the wafer to be coated including means for rotating the said wafer at a predetermined speed.

The electroplating method used in the examples included the following consecutive steps, performed in order:

### 1) Cold Entry:

The substrate was introduced into the electrolytic cell so that the surface having the cobalt liner layer is brought into contact with the electrolyte at an open-circuit condition. This contacting step generally lasts about 5 seconds or less or about 2 seconds or less or about 1 second or less and is carried out while the electrolytic cell is not electrically powered.

### 2) Formation of the Copper Coating:

The cathode assembly was then polarized in constant-current mode in a range of current and at the same time rotated at a speed of 20 to 200 rounds per minute. The duration of the electroplating step was around 7 seconds to obtain a coating of about 2 nm on the conductive substrate.

### 3) Hot Exit:

After the electroplating step, the copper-coated cathode was withdrawn from the electroplating solution with the prior speed of rotation, while being maintained under voltage bias. The duration of this phase was about 2 seconds.

Deionized water rinses were then carried out on the copper coated substrate and the substrate was dried.

### Example 1

This example describes a copper layer formed by an electrolyte that does not contain a polar solvent.

Thin layers of copper of 0.3 to 3 nm thickness were deposited onto a blanket cobalt liner. The substrate consisted of a piece of silicon wafer, covered with a blanket silicon dioxide dielectric layer and itself coated with a thin layer of copper diffusion barrier, such as tantalum nitride or titanium nitride, and a 16 nm-thick CVD cobalt liner. The substrate sheet resistance was in the range of 9-10 obm/sq.

Prior to deposition, the cobalt substrate was immersed in a pretreatment solution to remove cobalt surface oxide. The pretreatment solution contained a diluted weak acid such as 5 g/l citric acid, or ligands which complex with cobalt cations. The pretreatment step typically lasts about 0-30 seconds and is followed by deionized water rinse. The pretreatment step can be skipped in the case of fresh cobalt substrates.

Next, the substrate is transferred into the plating solution described below and maintained at open-circuit condition for 0-30 sec. Thereafter, the cobalt cathode was polarized in constant-current mode in a range of current from 2 mA/cm² to 10 mA/cm². The plating solution was adjusted to a pH of about 8.9 and maintained at the pH level for the duration of the test.

| | Concentration |
|---|---|
| Component | (g/L) |
| Copper Sulfate | 50.69 |
| Diethylenetriamine | 6.5 |
| Lupasol ® SC-61B | 18.5 |
| Water | 918.71 |

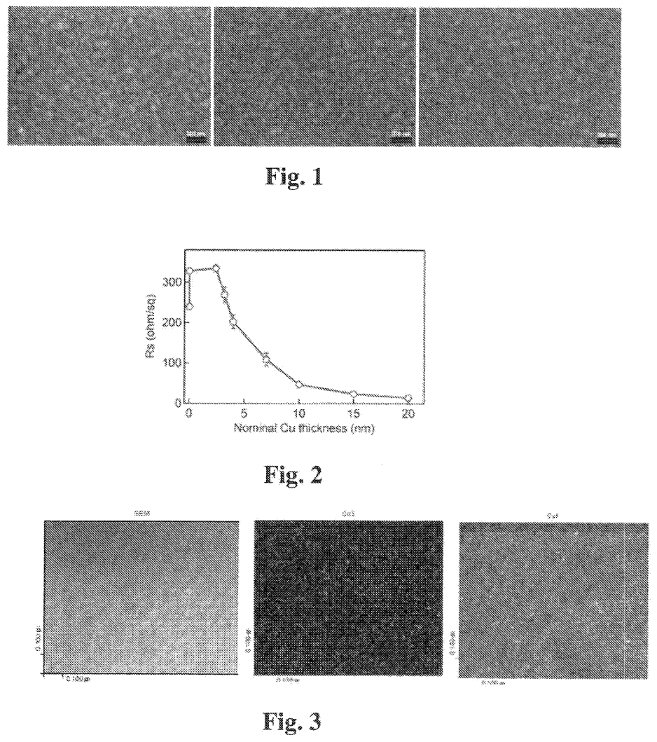

FIG. 1 depicts surface morphologies of different copper amounts deposited on cobalt substrates. About one monolayer copper coated substrate in FIG. 1(b) shows same surface morphology as the substrate, implying copper conformal layer growth on cobalt at the initial stage. As more copper is deposited on the surface, root-mean-square surface roughness decreases from 2.6 nm in FIG. 1(a) when no copper is on the surface to 2.1 nm in FIG. 1(c) when 1.6 nm copper is coated. Copper thin films deposited from plating solution described in this example do not roughen the substrate. Instead, the thin copper films smoothen the substrate and the surface exhibits reduced surface roughness as compared to a bare cobalt layer. As a thicker copper layer is deposited (i.e., about 4 to 5 nm), the surface topography of the cobalt substrate disappears. No characteristic markers are observed on the surface due to the absence of hydrogen evolution and copper displacement.

### Example 2

This example describes a copper layer formed using an electrolyte that contains a polar solvent (i.e., glycerol).

Thin layers of copper of 0.3 to 3 nm thickness were deposited on a blanket cobalt liner. The substrate consisted of a piece of silicon substrate, covered with a blanket silicon dioxide dielectric layer and itself coated with a thin layer of diffusion barrier, such as tantalum nitride or titanium nitride, and a 3 nm-thick CVD cobalt liner. The substrate sheet resistance is in the range of 200-300 ohm/sq.

Prior to deposition, the cobalt substrate was immersed in a pretreatment solution to remove cobalt surface oxide. The pretreatment solution may contain diluted weak acid such as 0.5 g/l citric acid, or ligands which complex with cobalt cations. The pretreatment typically lasts about 0-30 sec and was followed by deionized water rinse. The pretreatment step can be skipped in the case of fresh cobalt substrates.

Next the substrate was transferred into the plating solution described below and maintained at open-circuit condition for 0 to 30 sec. Then the cobalt cathode was polarized in constant-current mode in a range of current from 0.5 mA/cm² to 3 mA/cm². The composition was adjusted to a pH of about 8.9 and maintained at the pH level for the duration of the test.

| | Concentration |
|---|---|
| Component | (g/L) |
| Copper Sulfate | 5.1 |
| Diethylenetriamine | 0.514 |
| Lupasol ® SC-61B | 3.7 |
| Glycerol | 200 |
| Water | 839 |

FIG. 2 depicts the dependence of substrate sheet resistance on the nominal thickness of copper films. The sheet resistance drops at a nominal thickness of 3 nm, which roughly corresponds to 1 nm true thickness due to low coulombic efficiencies at initial growth stage. This observation shows that the copper film coalescence achieves earlier than reaching 1 nm thickness, indicating extremely high copper nucleation density on cobalt.

FIG. 3 depicts the Auger surface mapping of a thin copper film of 1.4 nm thickness on a cobalt substrate with low impurity levels. The escaped depth of cobalt Auger electrons is about 1.2 nm, slightly shorter than the copper film thickness. The dominant overlayer copper intensity shown in FIG. 3(c) and the noise-level underlayer cobalt intensity shown in FIG. 3(b) indicate a compact, surface pinhole-free copper film.

### Example 3

This example demonstrates that thin layers of copper can be formed not only on a cobalt liner, but also on other conductive substrates including, but not limited, to tungsten, molybdenum, and ruthenium.

Substrates used in this example consisted of a piece of silicon wafer, covered with a blanket silicon dioxide dielectric layer and a CVD tungsten layer. The electrical sheet resistance of this substrate is in the range of 0.3-0.4 ohm/sq.

Prior to deposition, the tungsten substrate may be immersed in a pretreatment solution to remove tungsten surface oxide. The pretreatment solution may contain diluted weak acid such as 5 g/l citric acid, or ligands which complex with tungsten cations. The pretreatment typically lasts 0-30 sec and followed by deionized water rinse. The pretreatment step may be skipped in the case of fresh tungsten substrates. Next the substrate is transferred into the copper plating solution, and stays at open-circuit condition for 0-30 sec. Then the tungsten cathode was polarized in constant-current mode in a range of current from 0.5 mA/cm² to 5 mA/cm².

The composition was adjusted to a pH of about 9.2 and maintained at the pH level for the duration of the test. Thin copper films of 6 nanometer thickness were deposited on tungsten substrates using the following plating solution:

| | Concentration |
|---|---|
| Component | (g/L) |
| Copper(II) Sulfate | 5.1 |
| Diethylenetriamine | 0.15 |
| N,N,N,N-Tetrakis(2-Hydroxypropyl) | 3.93 |
| ethylenediamine | |
| Ethylenediaminetetraacetic acid | 0.41 |
| Tetraethylammonium hydroxide | 1.4 |
| Glycerol | 200 |
| Water | 839 |

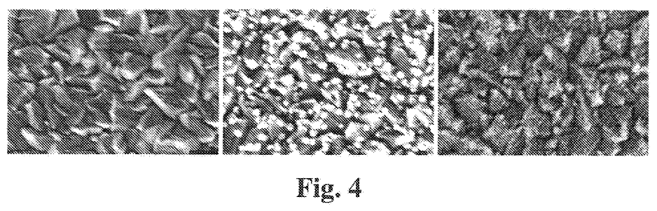

Demonstrated in FIG. 4 are surface morphologies of copper electrodeposition on tungsten substrates at different process stages or conditions. FIG. 4(a) shows coarse grains of as-received CVD tungsten films of grain sizes around 300 nm. If no surface pretreatment prior to copper deposition, aggregations of copper particles of about 40 diameters form on the tungsten substrate as shown in FIG. 4(b). On the contrary, copper forms a conformal coating layer on tungsten grains with the help of appropriate surface pretreatment as shown in FIG. 4(c).

The examples demonstrate that it is possible to produce an ultrathin copper layer from an alkaline electrolyte on various conductive substrates. This ultrathin copper layer can then be subsequently processed, if desired, to fill electrolytically deposit copper on the ultrathin copper layer. As described herein, the ultrathin copper layer was shown to provide a pin-hole free copper deposit on conductive substrates that was capable of preventing dissolution.

1. A copper electrolyte comprising:
a. a water soluble copper salt;
b. a complexant;
c. a leveler;
d. optionally a polar solvent;
e. optionally, a pH adjuster; and
f. balance water,
wherein the copper electrolyte has a pH in the range of about 8 to about 11.

2. The copper electrolyte according to claim 1, wherein the water soluble copper salt comprises a copper (II) salt.

3. The copper electrolyte according to claim 2, wherein the copper (II) salt is selected from the group consisting of copper (II) sulfate, copper (II) chloride, and copper (II) acetate.

4. The copper electrolyte according to claim 3, wherein the copper (II) salt comprises copper (II) sulfate.

5. The copper electrolyte according to claim 1, wherein the complexant is selected from the group consisting of citric acid, tartaric acid, ethylenediaminetetraacetic acid (EDTA), N-(hydroxyethyl)-ethylenediaminetriacetic acid (HEDTA), ethylenediamine, 1,6 diamino-cyclohexane, diethylene-triamine, triethylene-tetramine, N,N,N,N-tetramethyl-ethylene-diamine, N,N-Bis(2-hydroxyethyl)ethylenediamine, N,N,N,N-tetrakis(2-hydroxyethyl)ethylenediamine, glycine, 2-amino-ethyl-phosphonic acid, salicylic acid, salicylhydroxamic acid, catechol, 1,2-dihydroxybenzene-4-sulfonic acid, acetylacetone, acetylacetonate, dimethylglyoxime and 1,3-diamino-propane.

6. The copper electrolyte according to claim 5, wherein the complexant comprises diethylenetriamine.

7. The copper electrolyte according to claim 1, wherein the leveler is selected from the group consisting of polyethylene imine and derivatives thereof, quaternized polyethylene imine, polyglycine, poly(allylamine), polyaniline, polyurea, polyacrylamide, poly(melamine-co-formaldehyde), reaction products of amines with epichlorohydrin, reaction products of an amine, epichlorohydrin, and polyalkylene oxide, reaction products of an amine with a polyepoxide, polyvinylpyridine, and polyvinylimidazole.

8. The copper electrolyte according to claim 1, wherein the pH adjuster is selected from the group consisting of tetraethylammonium hydroxide and tetrabutylammonium hydroxide.

9. The copper electrolyte according to claim 1, wherein the polar solvent is present in the electrolyte and is selected from the group consisting of ethylene glycol, propylene glycol, glycerol, ethylene glycol monomethyl either, ethylene glycol monoethyl ether, ethylene glycol monopropyl ether, dipropylene glycol monomethyl ether and combinations of the foregoing.

10. The copper electrolyte according to claim 9, wherein the polar solvent is glycerol.

11. The copper electrolyte according to claim 1, comprising:
a. about 40 to about 80 g/L of the water soluble copper salt;
b. about 4 to about 20 g/L of the complexant; and
c. about 15 to about 25 g/L of the leveler.

12. The copper electrolyte according to claim 9, comprising:
a. about 2 to about 25 g/L of the water soluble copper salt;
b. about 0.1 to about 2.0 g/L of the complexant;
c. about 2 to about 8 g/L of the leveler; and
d. about 150 to 250 g/L of the polar solvent.

13. A copper electrolyte consisting essentially of:
a. a water soluble copper salt;
b. a complexant;
c. a leveler;
d. 0 to 300 g/L of a polar solvent;
e. optionally, a pH adjuster; and
f. balance water,
wherein the copper electrolyte has a pH in the range of about 8 to about 11.

14. A copper electrolyte consisting of:
a. a water soluble copper salt;
b. a complexant;
c. a leveler;
d. 0 to 300 g/L of a polar solvent;
e. optionally, a pH adjuster; and
f. balance water,
wherein the copper electrolyte has a pH in the range of about 8 to about 11.

15. A method of depositing a copper film on a conductive substrate, the method comprising the steps of:
a) optionally, pretreating the conductive substrate, wherein the pretreatment step removes surface oxides; and
b) immersing the conductive substrate into a copper electrolyte, wherein the copper electrolyte comprises:
a. a water soluble copper salt;
b. a complexant;
c. a leveler;
d. optionally a polar solvent;
e. optionally, a pH adjuster; and
f. balance water,
wherein the copper electrolyte has a pH in the range of about 8 to about 11, and
c) electrodepositing the copper film on the conductive substrate using the copper electrolyte described herein, wherein the copper film is an ultrathin copper film having a thickness of less than about 5 nm, wherein the ultrathin copper film is a continuous copper film that is free of any pinholes or other defects.

16. The method according to claim 15, wherein the pretreatment step comprises contacting the conductive substrate with a pretreatment solution containing a dilute weak acid.

17. The method according to claim 16, wherein the dilute weak acid comprises a solution of citric acid.

18. The method according to claim 15, wherein the ultrathin copper film has a thickness of less than 4 nm.

19. The copper electrolyte according to claim 1, wherein the copper electrolyte has a pH in the range of about 8.2 to about 9.5.
